(19) United States
(12) Patent Application Publication
(10) Pub. No.: US 2006/0275547 A1
(43) Pub. Date: Dec. 7, 2006

(54) Vapor Phase Deposition System and Method

(76) Inventors: Chung J. Lee, Fremont, CA (US); Atul Kumar, Santa Clara, CA (US); George Tzeng, Oakland, CA (US); Oanh Nguyen, Union City, CA (US)

Correspondence Address: ALLEMAN HALL MCCOY RUSSELL & TUTTLE LLP, 806 SW BROADWAY, SUITE 600, PORTLAND, OR, 97205-3335, US

(21) Appl. No.: 11/421,385

(22) Filed: May 31, 2006

Related U.S. Application Data
(60) Provisional application No. 60/686,677, filed on Jun. 1, 2005.

(51) Int. Cl. C23C 16/00

(52) U.S. Cl. 427/248.1; 361/143

(57) ABSTRACT

A system for depositing a vapor phase organic compound onto a substrate, comprising a vacuum chamber comprising a wall, a wall heater in thermal communication with the wall of the vacuum chamber, at least one of an evaporative source and a transport polymerization source configured to introduce the vapor phase organic compound into the chamber, and a substrate holder disposed within the vacuum chamber, wherein the substrate holder comprises a cooled chuck, a heat transfer gas source for introducing a heat transfer gas to a space between the cooled chuck and the substrate, and a substrate clamping mechanism comprising at least one of an electrostatic, mechanical and magnetic clamping mechanism.

### CROSS-REFERENCE TO RELATED APPLICATIONS

This application claims priority to U.S. Provisional Patent Application Ser. No. 60/686,677, entitled TEMPERATURE-CONTROLLED SUBSTRATE HOLDING SYSTEM and filed Jun. 1, 2005, the disclosure of which is hereby incorporated by reference.

### TECHNICAL FIELD

The present disclosure relates to a system and method for performing a vapor phase deposition of an organic material.

### BACKGROUND

Many different types of devices include thin films of organic materials deposited by vapor phase methods. For example, organic light emitting devices (OLEDs) generally include two or more layers of organic materials stacked between conducting electrodes. When electrical current flows through this stack, light is emitted by the organic layers. OLEDs may also include one or more organic polymer protectant layers to protect the light-emitting layers from oxygen, water vapor, and other atmospheric contaminants. For example, encapsulation structures formed from organic layers and combinations of organic/inorganic materials may help to minimize environmental damage from oxygen and water vapor. Additionally, thin organic layers deposited between organic light emitting material and electrodes may help to decrease the formation of dark spots and extend device lifetimes.

Displays made out of OLEDs are widely considered to be a future replacement for liquid crystal displays (LCDs). OLED technology is considered superior to LCD technology for several reasons. First, an OLED is an emissive system, creating its own light rather than relying on modulating a backlight. This may lead to higher contrast, truer colors, crisper display of motion, and potentially less power consumption. Additionally, the OLED display manufacturing process is less expensive and simpler compared to that of the LCD display.

However, one potential problem with current OLED display manufacturing processes is poor material utilization rate of the source organic materials deposited by thermal evaporation. In current manufacturing processes, significant amounts of organic precursor materials may be deposited on the chamber walls, substrate holder, and other structures within the chamber. This may result in lower deposition yield on the substrate, and therefore greater materials expenses for a manufacturing process. Furthermore, the walls of the chamber and other internal deposition system structures may require periodic cleaning to remove the deposited materials. This may result in additional tool maintenance downtime, thus further increasing manufacturing costs.

### SUMMARY

One embodiment provides a system for depositing a vapor phase organic compound onto a substrate, wherein the system comprises a vacuum chamber comprising a wall, a wall heater in thermal communication with the wall of the vacuum chamber, at least one of an evaporative source and a transport polymerization source configured to introduce the vapor phase organic compound into the chamber, and a substrate holder disposed within the vacuum chamber, wherein the substrate holder comprises a cooled chuck, a heat transfer gas source for introducing a heat transfer gas to a space between the cooled chuck and the substrate, and a substrate clamping mechanism comprising at least one of an electrostatic, mechanical and magnetic clamping mechanism.

### BRIEF DESCRIPTION OF THE DRAWINGS

FIG. 1 is a block diagram of an embodiment of a vapor phase film deposition system.

FIG. 1a is a block diagram of an alternate embodiment of a vapor phase film deposition system.

FIG. 2 is a schematic depiction of an embodiment of a temperature controlled substrate holder and deposition chamber.

FIG. 3 is a partially broken away view of another embodiment of a substrate holder and deposition chamber.

FIG. 4 is a partially broken away view of the deposition chamber and substrate holder of FIG. 3.

FIG. 5 is a magnified view of a substrate lifting apparatus of the substrate holder of FIG. 3.

FIG. 6 is an exploded perspective view of a portion of a chuck of the substrate holder of FIG. 3.

FIG. 7 is a schematic depiction of another embodiment of a temperature controlled substrate holder.

FIG. 8 is a schematic depiction of an embodiment of an intermediate substrate contact of the substrate holder of FIG. 7.

FIG. 9 is a schematic depiction of another embodiment of an intermediate substrate contact of the substrate holder of FIG. 7.

FIG. 10 is a schematic depiction of another embodiment of an intermediate substrate contact of the substrate holder of FIG. 7.

FIG. 11 is a top schematic view of an embodiment of a magnetically clamping cooling chuck.

FIG. 12 is a side schematic view of the embodiment of FIG. 11.

FIG. 13 is a top schematic view of another embodiment of a magnetically clamping cooling chuck.

FIG. 14 is a side schematic view of the embodiment of FIG. 13.

FIG. 15 is a side schematic view of the embodiment of FIG. 11 oriented in a face-down configuration.

FIG. 16 is an isometric view of an alternate embodiment of a clamping member.

FIG. 17 is a magnified view of a portion of the clamping member of FIG. 16.

### DETAILED DESCRIPTION OF THE DEPICTED EMBODIMENTS

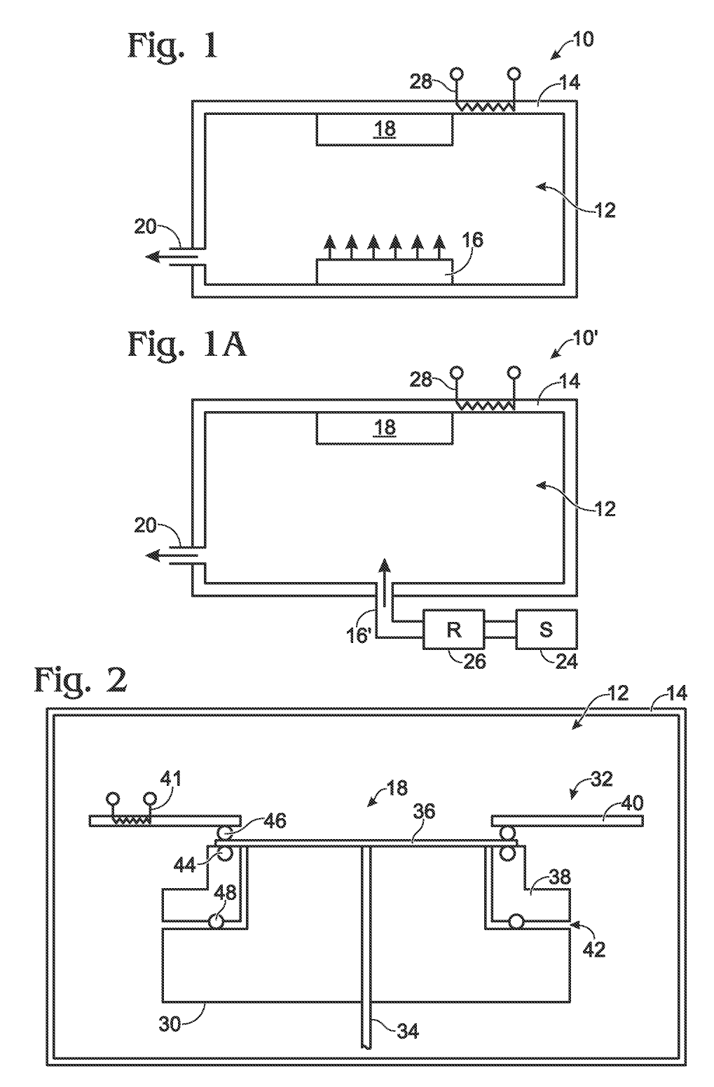

FIGS. 1 and 1A show two exemplary embodiments of a vapor phase deposition system for performing a vapor phase deposition of an organic compound onto a substrate. Referring first to FIG. 1, deposition system 10 includes a chamber 12 having a heated wall 14, an organic compound evaporation source 16, a temperature-controlled substrate holder 18, and an outlet 20. Outlet 20 may be connected to a pumping system (not shown) to allow system 10 to be maintained under a vacuum for a deposition process. Deposition system 10 may alternately include a heated substrate clamp 22 for clamping a substrate to the temperature-controlled substrate holder, as described in more detail below.

Referring next to FIG. 1A, deposition system 10′ includes many of the same components as deposition system 10, but is configured for performing a transport polymerization deposition process, rather than an evaporation deposition process. As such, deposition system 10′ includes a precursor source 24, and may also include a reactor 26 for forming a reactive intermediate compound from the precursor compound.

Deposition systems 10 may be used to deposit various types of organic compounds. For example, in the context of OLED displays, deposition system 10 may be used to deposit many different organic layers, including but not limited to layers of the electron transport/light emitter aluminum tris(8-hydroxyquinoline) (“Alq3”); the light emitter 4,4′-bis(2,2′ diphenyl vinyl)-1,1′-biphenyl (“DPVBi”); and dopants coumarin 6 green, and QA green.

Likewise, system 10′ may be used to deposit polymer films such as parylene-based thin films via transport polymerization. These films may be used in combination with layers of inorganic materials to encapsulate an OLED display to protect the organic light emitting materials, as well as other layers such as cathode and anode layers, from oxygen, water vapor, and other atmospheric oxidants. As used herein, the term “parylene-based” includes, but is not limited to, poly(paraxylylene) polymers having a general repeat unit of (-CZ¹Z²-Ar-CZ³Z⁴-), wherein Ar is an aromatic (unsubstituted, partially substituted or fully substituted), and wherein Z¹, Z², Z³ and Z⁴ are similar or different. In specific embodiments, Ar is C₆H₄₋ₓXₓ, wherein X is a halogen, x is zero or an integer of 1-4, and each of Z¹, Z², Z³ and Z⁴ individually are H, F or an alkyl or aromatic group. In one specific embodiment, a partially fluorinated parylene-based polymer known as “PPX-F” is used. This polymer has a repeat unit of (—CF₂—C₆H₄—CF₂—), and may be formed from various precursors, including but not limited to BrCF₂—C₆H₄—CF₂Br. In another specific embodiment, fully fluorinated poly(paraxylylene) is used. This polymer has a repeat unit of (—CF₂—C₆F₄—CF₂—). In yet another specific embodiment, unfluorinated poly(paraxylylene) (“PPX-N”) is used. This polymer has a repeat unit of (—CH₂—C₆H₄—CH₂—). It will be appreciated that these specific embodiments of parylene-based polymer films are set forth for the purposes of example, and are not intended to be limiting in any sense. Furthermore, other materials besides parylene-based polymers may also be deposited via transport polymerization with system 10′.

Transport polymerization of parylene-based films involves generating a gas-phase reactive intermediate from a precursor molecule at a location remote from a substrate surface and then transporting the gas-phase reactive intermediate to the substrate surface, wherein the substrate surface is kept below the boiling temperature of the reactive intermediates for polymerization. For example, PPX-F may be formed from the precursor BrCF₂—C₆H₄—CF₂Br by the removal of the bromine atoms to form the reactive intermediate *CF₂—C₆H₄—CF₂* (wherein * denotes a free radical) at a location remote from the deposition chamber. In system 10′, for example, this reaction may take place in reactor 24. The reactive intermediate may then be transported into the deposition chamber and condensed onto a substrate surface, where polymerization takes place. Careful control of deposition chamber pressure, reactive intermediate feed rate and substrate surface temperature can result in the formation of a polymer film having a high level of initial crystallinity. The film may then be annealed to increase its crystallinity and, in some cases, to convert it to a more dimensionally and thermally stable phase.

The combination of temperature-controlled substrate holder 18, heated wall 14 and heated substrate clamp 22 may allow high deposition yields to be achieved for some organic molecules relative to deposition systems without these features. For example, in the specific example of PPX-F, the deposition rate of a PPX-F film onto a glass substrate is about 2300 Å/min at a substrate holder temperature of −40° C., about 400 Å/min at −10° C., and about 60 Å/min at 20° C. with a constant precursor feed rate of 3 sccm. From these data, it can be seen that the sticking coefficient of the PPX-F reactive intermediate (i.e. a proportion of the reactive intermediate hitting the substrate surface that adsorbs to the substrate surface) may have a value on the order of 38 times greater at −40° C. than at 20° C. Increasing the temperature of the deposition chamber walls, as well as other non-substrate surfaces in the chamber, may help to reduce or even eliminate the deposition of materials on these surfaces, and may therefore further help to increase the yield of deposited material on a substrate. In general, the substrate temperature may be maintained between the melting point of the reactive intermediate and the lower of the ceiling temperature of the polymerization reaction (the temperature above which the polymerization reaction does not occur at a desired rate) and the boiling temperature of the reactive intermediate, while all other components in the chamber may be maintained at a temperature higher than either the ceiling temperature of the deposition reaction or the boiling temperature of the precursor.

Likewise, in the specific example of the deposition of an organic light emitting compound by evaporation, the temperature of the evaporation source may be as high as 300° C. Convective heating of the substrate caused by the evaporated source material may cause the substrate to be heated to temperatures as high as 40-50° C. during deposition, in the absence of substrate cooling. Where the chamber walls do not include a heating mechanism, the walls may have a temperature on the order of 20-30° C. lower than that of the substrate. This may result in the deposition of more material on the chamber walls than on the substrate, and may lead to substrate deposition yields of only 5-10%.

The combination of the temperature-controlled substrate holder 18, heated wall 14 and optional heated substrate clamp 22 may help to maintain a suitably low substrate temperature, for example, on the order of −20° C. to −40° C., during the evaporation deposition of an organic light emitting compound. Furthermore, heating walls 14, substrate clamp 22, and/or other structures within chamber 12 may help to prevent the condensation of the organic material onto these structures, thereby increasing the percentage of organic material that deposits on the substrate, and thus increasing the deposition yield.

Walls 14 and clamp 22 may be heated to any suitable temperature. Suitable temperatures for many compounds may include, but are not limited to, temperatures between approximately 20° C. and 65° C. If wall temperatures higher than 65° C. are used, it may be desirable to surround chamber 12 with an insulating structure (not shown) for safety purposes. Substrate and wall temperatures within these ranges may allow deposition yields on the order of 20% or higher to be achieved. This may provide significant cost advantages relative to the evaporation of organic light emitting materials without substrate cooling and chamber wall heating. For example, the costs of some organic light emitting materials can be as high as $300/gram. The cost of utilization of such a material on a single OLED production line may be on the order of approximately $40 million/year. Using these values, the achievement of deposition yields of 20-22% may offer savings of approximately $16 million/year per production line compared to deposition yields of 10-12%. It will be appreciated that wall and/or substrate holder heating may be omitted where the boiling point of a desired material or ceiling temperature of a desired reaction is below the equilibrium temperature of the chamber walls during a deposition process in the absence of heating.

Walls 14 of chamber 12 may be heated in any suitable manner. For example, walls 14 may include a resistive heating element incorporated into the walls, as indicated at 28. Alternatively, chamber 12 may be substantially surrounded by a heater, such as a resistive heater, radiative heater, etc.

Temperature-controlled substrate holder 18 may be configured to hold and cool a substrate in any suitable manner. For example, substrate holder 18 may include an electrostatic chuck that generates an electrostatic clamping force between a substrate and an underlying temperature-controlled chuck. In alternate embodiments, substrate holder 18 may include mechanical and/or magnetic clamping mechanisms. Such clamping mechanisms may provide advantages in holding substrates for the fabrication of OLEDs. OLEDs are commonly fabricated on electrically insulating substrates that may not adhere well to an electrostatic temperature-controlled chuck due to the electrically insulating properties of glass, even where voltages as high as 50 kV are applied to the substrate and chuck. Furthermore, residual static charge may remain on such a substrate after the voltage is removed from the chuck and the wafer, which may damage devices formed on the substrate. It may be possible to generate a sufficient clamping force between the chuck and an electrically insulating substrate by the application of voltages as high as 100 kV. However, such high voltages may also damage devices formed on the substrate. Deposition of a conductor such as indium tin oxide (ITO) on the front and back of a glass substrate may allow a greater electrostatic clamping force to be generated. However, the deposition of ITO would add additional process steps, and may not be compatible with some device manufacturing processes.

The use of a heat transfer gas between a temperature-controlled electrostatic chuck and substrate may create further difficulties where the substrate is electrically insulating. For example, to uniformly cool a glass substrate (for example, <5 degrees Celsius variation across device areas of the substrate in some embodiments, and less than 1-2 degrees Celsius in other embodiments) to a suitable temperature for depositing a PPX film, a pressure of at least 2 to 3 Torr of a suitable heat transfer gas, such as helium, and possibly as much as 4 to 5 Torr (or even greater), may be added in the space between the chuck and the substrate backside to provide sufficiently efficient heat transfer, and/or to maintain a desired substrate temperature during an evaporation deposition process, in which heat is transferred to the substrate convectively by the evaporated compound. However, in a vacuum environment, such a high pressure of gas against the substrate backside may overcome the electrostatic clamping force and cause the substrate to detach from the chuck. While helium is disclosed above as being a suitable heat transfer gas, it will be appreciated that other suitable heat transfer gases besides helium may also be used. Examples of other suitable heat transfer gases include, but are not limited to, argon and nitrogen.

FIG. 2 shows a schematic depiction of an exemplary embodiment of a substrate holder 18 that addresses these and other problems with the holding of electrically insulating substrates. Substrate holder 18 includes a temperature-controlled chuck 30 and a substrate clamping system 32. Substrate holder 18 also includes a heat transfer gas outlet 34 to allow the introduction of a heat transfer gas between chuck 30 and the backside of a substrate positioned on chuck 30. Temperature-controlled chuck 30 may be cooled in any suitable manner, including but not limited to the circulation of a cooling fluid or thermoelectric methods.

Substrate clamping system 32 is configured to clamp a substrate 36 sufficiently tightly to prevent deposition gases from penetrating the seals between the clamping members and the substrate, and to prevent helium or other heat transfer gas from escaping the space between the substrate 36 and temperature-controlled chuck 30. Substrate clamping system 32 includes a clamping base 38 and an opposing clamping member 40. Clamping base 38 is configured to hold substrate 36 in a desired position relative to temperature-controlled chuck 30, and clamping member 40 is movable relative to clamping base 38 to clamp and secure substrate 36 in substrate holder 18. Clamping member 40 includes a heater (shown here as a resistive heater 41) incorporated into clamping member 40.

The depicted clamping member 40 is configured to clamp uniformly around a perimeter portion of substrate 36. This forms a seal entirely around substrate 36, helping to prevent deposition gases from flowing into the space between substrate 36 and chuck 30, and also helping to prevent helium from escaping this space. In some embodiments, the separation between substrate 36 and chuck 30 is less than 100 microns. In other embodiments, the separation between substrate 36 and chuck 30 is 25-50 microns. In yet other embodiments, the spacing is greater than 100 microns.

In order to reduce the amount of heat transferred between heated clamping member 40 and temperature-controlled chuck 30, clamping base 38 may be separated from temperature-controlled chuck 30 by a space 42. Space 42 may help to prevent temperature-controlled chuck 30 from acting as a heat sink for clamping member 40 via the transfer of heat through substrate 36 and clamping base 38. Additionally, clamping base may be made of a material with poor thermal conductivity and/or low thermal mass. Examples of suitable materials include, but are not limited to polyimides, polyethersulfone and polyetherimide.

Thermally-insulating standoffs (not shown) may be used to insulate temperature-controlled chuck 30 from the surface of the deposition chamber to which the chuck is mounted or otherwise coupled to provide further thermal isolation of the chuck from heated deposition chamber walls.

In some embodiments, one or more seals, gaskets, O-rings or other such structures may be provided on clamping base 38 and/or clamping member 40 to help form a seal around the perimeter of substrate 36. For example, in the depicted embodiment, a first seal 44 is provided between clamping base 38 and substrate 36, and a second seal 46 is provided between clamping member 40 and substrate 36. Seal 44 helps to prevent helium from leaking out of the space between temperature-controlled chuck 30 and substrate 36, and seal 46 helps to prevent deposition gases from contaminating this space. Seals 44 and 46 also help to accommodate substrates of non-uniform thickness via the compression of seals 44 and 46 during clamping. Furthermore, seals 44 and 46 may help to restrict the transfer of heat from clamping member 40 to clamping base 38. An additional seal 48 may be used between temperature-controlled chuck 30 and clamping base 38 to help prevent helium leakage and to provide additional thermal insulation between temperature-controlled chuck 30 and clamping base 38.

Seals 44 and 46 may be made from any suitable material or materials. Suitable materials include materials with sufficiently low gas permeabilities to prevent unwanted gas leakage, and also include materials with glass transition temperatures below temperatures at which substrate 36 is held during deposition processes so that the seals do not convert to a glassy state upon substrate cooling. In a specific embodiment, seal 44 is formed from a material capable of limiting a leakage rate of helium to approximately 0.6 mTorr/minute or lower (and in some embodiments, less than 0.3-0.4 mTorr/minute) where the helium has a pressure of approximately 3-5 Torr. It will be appreciated that this is merely one example of a suitable leak rate, and that different deposition processes may have different leak rate tolerances.

It has been found that effective temperature gradients may be maintained between the substrate 36 and clamping member 40 through the use of seals 44, 46, and 48 and the separation of clamping base 38 from temperature-controlled chuck 30. For example, in one experiment, the temperature of the substrate was successfully held at −35 degrees Celsius while the temperature of clamping member 40 was held at 10 degrees Celsius. To achieve this substrate temperature, temperature-controlled chuck 30 was held at −40 degrees Celsius.

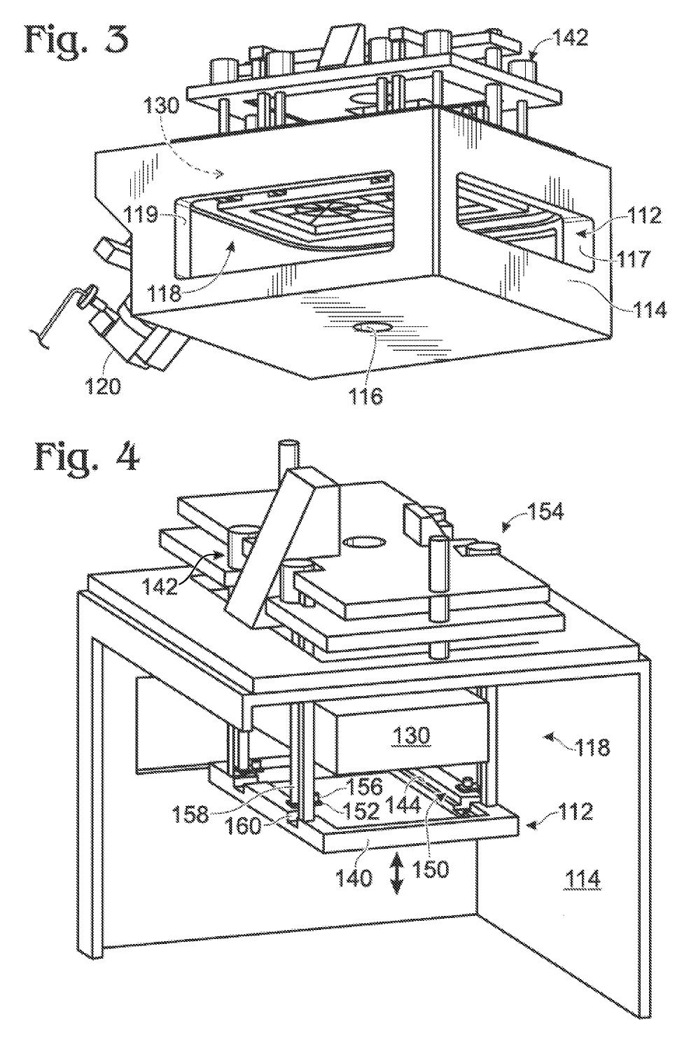

FIG. 3 shows a view of an exemplary embodiment of a deposition chamber 112. Chamber 112 is depicted as a face-down deposition chamber, in which a substrate is held such that the surface on which devices are fabricated faces downwardly. Chamber 112 includes a temperature-controlled substrate holder 118 positioned within an interior of the chamber in a face-down orientation. Chamber 112 also includes a heated wall 114, an opening 116 for admitting a flow of a vapor phase compound for deposition, and an outlet 120 to which a pumping system may be coupled to allow a vacuum to be formed in the chamber. Chamber 112 further includes an opening 117 for admitting the insertion of a substrate into the chamber, and one or more view ports 119. Opening 117 may be configured to accept attachment of a load lock or to be attached to other tools in a vacuum production line.

Substrate holder 118 includes a heated clamping member 140 and a temperature-controlled chuck 130. Clamping member 140 is coupled with a movement system 142 to allow clamping member 140 to be moved in a vertical direction relative to temperature-controlled chuck 130, as shown in FIG. 4. This permits a substrate to be clamped into substrate holder 118 by first moving clamping member 140 downwardly, inserting the substrate between the clamping member 140 and temperature-controlled chuck 130, and then moving clamping member 140 upwardly to clamp the substrate between the clamping member 140 and the temperature-controlled chuck 130. Clamp movement system 142 may employ any suitable mechanism to effect the movement of clamping member 140 relative to temperature-controlled chuck 130. Examples include, but are not limited to, hydraulic systems, mechanical systems, etc.

While the depicted embodiment utilizes lifting system 142 to move clamping member 140 relative to temperature-controlled chuck 130, it will be appreciated that clamp movement system 142 may also be configured to move temperature-controlled chuck 130 relative to clamping member 140, or may be configured to move both temperature-controlled chuck 130 and clamping member 140 relative to other structures in chamber 112 to effect clamping of a substrate onto substrate holder 118. Furthermore, while chamber 112 is depicted as a face-down chamber, it will be appreciated that chamber 112 may be configured as a face-up chamber (in which the substrate face on which devices are fabricated faces upwardly), a sideways-facing chamber (in which the substrate face on which devices are fabricated faces to the side), or in any other suitable manner. Likewise, while the depicted inlet opening 116 is positioned in a position opposite substrate holder 118 such that a deposition vapor flows in an average direction generally toward and perpendicular to the surface of the substrate, it will be appreciated that opening 116 may be located in any other suitable position. Furthermore, where chamber 112 is configured for use in evaporation depositions, opening 116 may be omitted and replaced by an evaporation source (not shown).

FIG. 4 also shows the construction of clamping member 140 in more detail. Clamping member 140 has a generally rectangular shape configured to clamp an outer perimeter of a rectangular substrate. Alternatively, clamping member 140 may have any other suitable shape, which may depend upon the substrate shape. Clamping member 140 includes a depression 144 configured to hold a substrate in a correct position relative to temperature-controlled chuck 130. In this manner, clamping member 140 also acts as a substrate holder. It will be appreciated that a substrate holder configured for use in a face-up orientation may include chuck or clamping base configured to act as a substrate holder.

FIG. 4 further shows an exemplary substrate lifting and positioning mechanism to assist in the automated loading and unloading of a substrate onto and off of substrate holder 118. The lifting and positioning mechanism includes a plurality of lifting members 150. Four lifting members are depicted, but any other suitable number may alternatively be used. Each lifting member 150 includes a substrate contact 152 configured to contact an edge portion of the device face of the substrate outside of the active device region of the substrate. Lifting members 150 are each connected to a lifting mechanism 154 that operates independently of clamp movement system 142 for clamping member 140. This permits lifting members 150 to move independently of clamping member 140, and thereby enables the lowering of a substrate into and the lifting of a substrate out of clamping member 140.

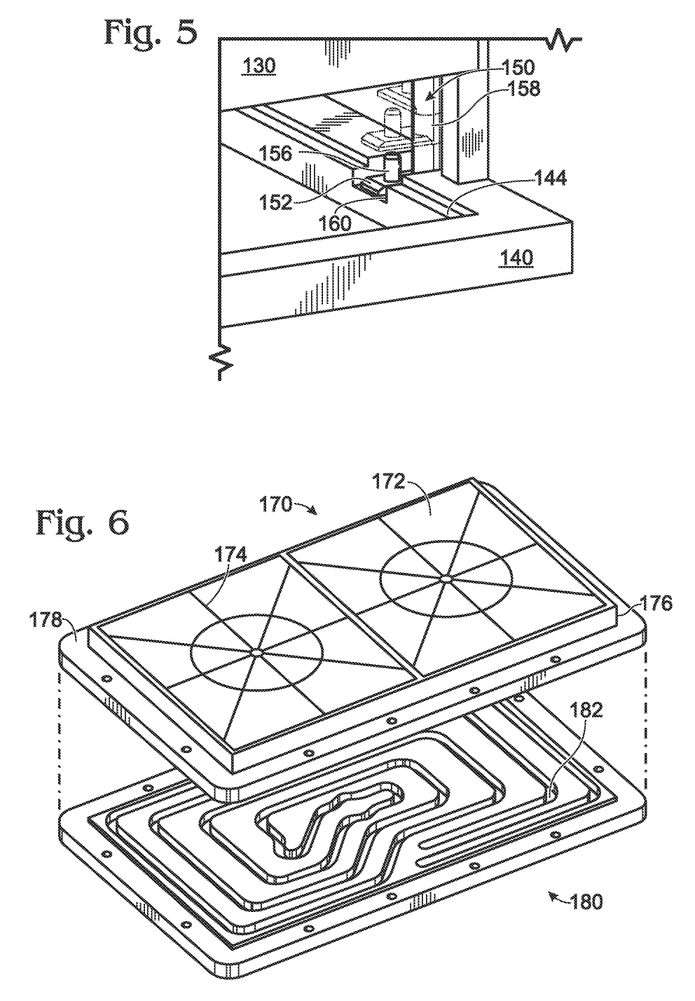

FIG. 5 shows an exemplary lifting member 150 in more detail. Lifting member 150 includes a positioning pin 156. Positioning pin 156 is configured to contact an edge of a substrate to push the substrate into a correct position for lowering into depression 144 in substrate holder 118. Lifting member 150 is rotatable about a long axis of a shaft 158 of the lifting member 150. This permits each positioning pin 156 to be rotated away from the substrate (as indicated in dashed lines in FIG. 5) for unloading and loading the substrate, which allows some margin of error in the position of a substrate being inserted into substrate holder 118. While the depicted embodiment shows positioning pins, it will be appreciated that any other suitable positioning structure other than pins may alternatively be used.

The insertion of a substrate into substrate holder 118 may proceed as follows. First, a substrate may be inserted in to chamber 112 through a load lock or other access mechanism (not shown) via a mechanical arm or other suitable mechanism. The substrate is positioned between lifting members 150, which are rotated such that the positioning pins 156 are spaced from the edges of the substrate. Next, lifting members 150 are each rotated, thereby bringing positioning pins 156 into contact with the substrate and bringing substrate contacts 152 beneath the substrate. After lifting members 150 have been fully rotated to bring positioning pins 156 into a fully inward position (as depicted in solid lines in FIG. 5), lifting members 150 are lowered to position the substrate within depression 144 in clamping member 140. Clamping member may include recesses 160 to accommodate substrate contacts 152. Once the substrate is positioned correctly within clamping member 140, clamping member 140 is raised to secure the substrate within the substrate holder 118 adjacent to temperature-controlled chuck 130.

While the embodiments of FIGS. 3-5 depict a face-down substrate holder, it will be appreciated that the concepts discussed in the context of these figures may also be adapted for use with face-up substrate holders, sideways-facing substrate holders, etc.

FIG. 6 shows an exploded view of some of the structures of temperature-controlled chuck 130 that contribute to the cooling abilities of temperature-controlled chuck 130. As depicted, temperature-controlled chuck includes an outer plate 170 configured to contact the backside of a substrate. Outer plate 170 includes a raised face portion 172 having plurality of surface grooves 174 to assist in the flow of helium across the face of outer plate 170 when a substrate is positioned on chuck 130. Outer plate also includes a seal 176 for sealing helium between face portion 172 and a substrate, and a perimeter lip region 178 configured to accommodate the clamping base positioned around the perimeter of face portion 172.

Temperature-controlled chuck 130 also includes a coolant substructure 180 positioned beneath outer plate 170. Coolant substructure 180 includes one or more coolant paths 182 formed therein, which provide a space in which a coolant fluid may flow and/or expand to remove heat from temperature-controlled chuck 130. It will be appreciated that FIG. 6 shows only a subset of the structures of temperature-controlled chuck 130 that provide for the cooling abilities of the chuck. Other structures that may be present but are not shown include, but are not limited to, a helium gas source (or other heat transfer gas source), a coolant compressor, various conduits, etc.

Referring again briefly to FIG. 2, the depicted clamping member 40 and clamping base 38 exert a clamping force on substrate 36 on only a narrow outer perimeter region of substrate 36. Therefore, depending upon the substrate size and physical properties, the pressure exerted by the helium between chuck 30 and substrate 36 may cause an outward bowing of the substrate. For example, bowing may occur with a rectangular glass substrate having side dimensions greater than approximately 600 mm×600 mm and a thickness of approximately 0.6 mm when approximately 4 Torr of helium is added to the space between the substrate and chuck. It will be appreciated that these values are merely exemplary and that substrates of other thicknesses, sizes and/or materials may have different deformation thresholds.

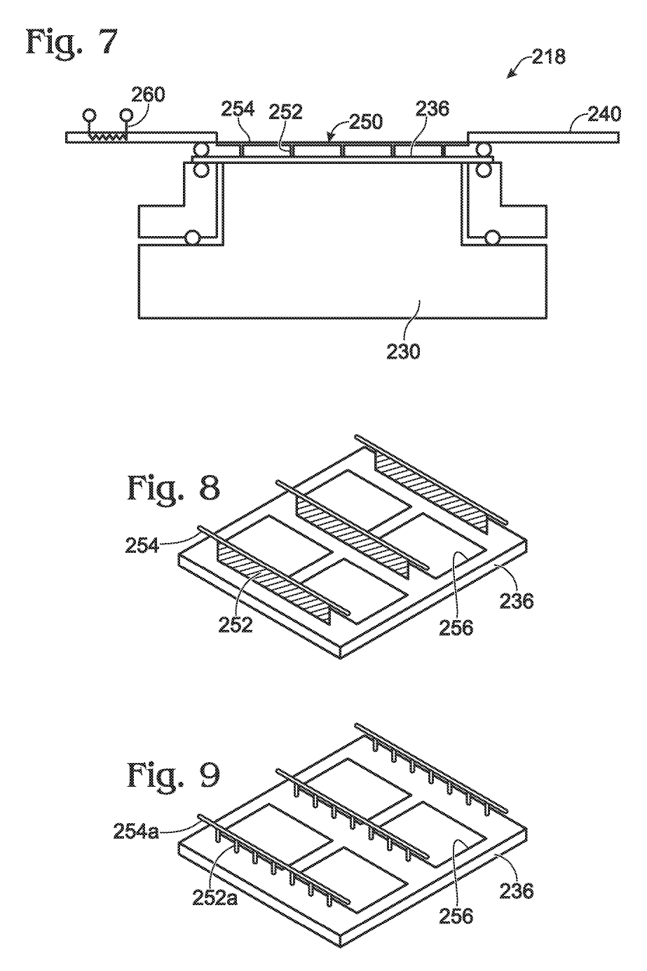

Substrate deformation may affect the growth of films on the substrate. However, the use of larger substrates may sometimes be desirable, as the use of larger substrates may allow larger numbers of devices to be fabricated on a single substrate and/or larger single devices to be fabricated. Therefore, referring to FIG. 7, in order to enable use with large surface area substrates, substrate holder 218 may include a clamping member 240 for clamping the perimeter of substrate 236, and an intermediate support structure 250 configured to support an intermediate or middle portion of substrate 236 against deformation from gas pressure. Support structure 250 includes one or more intermediate contacts 252 that contact substrate 236 at one or more locations between the edges of substrate 236, and a frame structure 254 that supports contacts 252. Contacts 252 may be positioned on locations along substrate 236 between regions on which devices are being fabricated. Alternatively, where a single device is being fabricated across substantially the entire substrate surface, contacts 252 may be configured to cover a small enough surface area as not to cause any noticeable effect in an image displayed on the resulting display device.

Any suitable number and configuration of contacts 252 may be used. For example, for a glass substrate having a thickness of approximately 0.6 mm, contacts 252 may be spaced at a distance of 500 mm or less, and preferably at a distance of 300 mm or less, along each dimension of the substrate. The actual spacing between contacts 252 may be determined by factors such as dimensions of the devices, the spacing between the devices being fabricated on the substrate, and the pressure differential across the substrate. Therefore, even where a substrate can be adequately supported by contacts 252 spaced at 300 mm intervals, spacings of 200 mm may be used where the sizes of plural devices being fabricated on the substrate are approximately 200 mm (including the spacing between the devices) along that dimension.

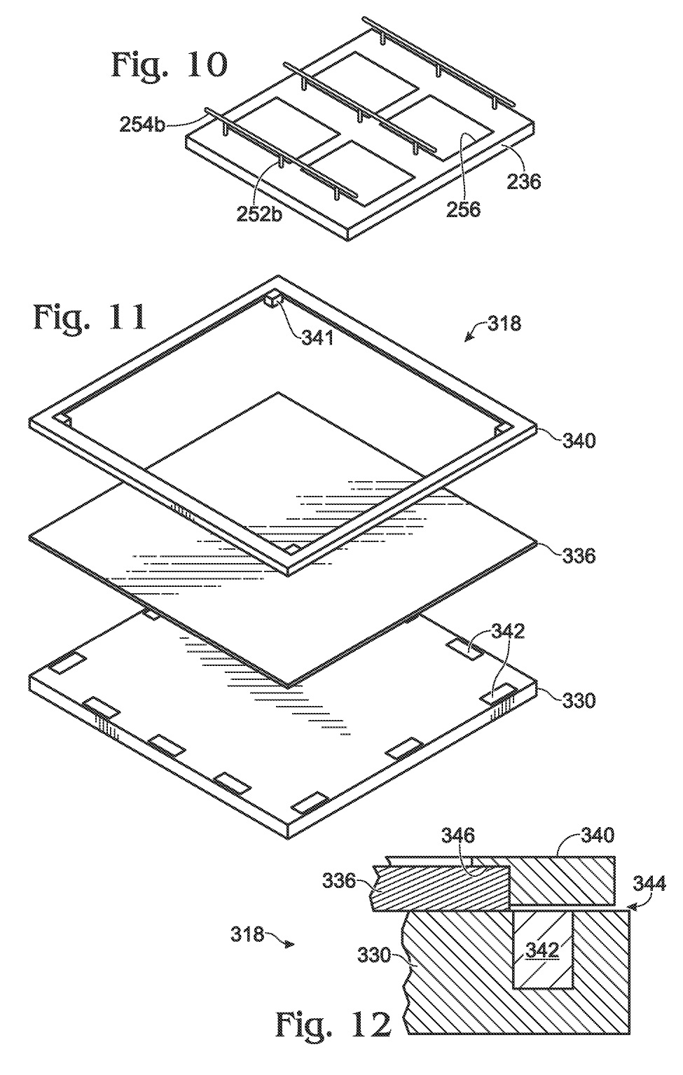

Contacts 252 and frame 254 may have any suitable configuration. Suitable configurations include configurations which do not block a flow of precursor or intermediate compound across the surface of substrate 236 to a detrimental extent. For example, as depicted in FIG. 8, contacts 252 may take the form of blade-like members. In another embodiment, the contacts may take the form of comb-like members with plural points of contact, as depicted at 252a in FIG. 9. In yet another embodiment, contacts 252 take the form of narrow, point-like members, as depicted at 252b in FIG. 10, that extend downwardly from frame 254 to contact substrate 236 at points approximately between the corners common to multiple devices on substrate 236. In yet another alternative embodiment, chuck 230 is an electrostatic chuck, and the electrostatic forces are used to prevent bowing while the substrate clamping mechanism is used to hold substrate 236 in place. In this embodiment, the electrostatic forces may be used in combination with support structure 250 to help prevent bowing, or without support structure 250. While each of these examples shows multiple intermediate contacts, it will be appreciated that support structure 250 may include only a single contact in some embodiments.

In the embodiments of FIGS. 7-10, contacts 252 may be oriented parallel to a direction of gas flow across the substrate, or may be oriented at least partially transverse to the direction of gas flow, depending upon the structure of the contacts (e.g. comb-like vs. blade-like), the nature of the film being deposited, and/or the nature of the devices being fabricated. Furthermore, frame 254 may be connected to clamping member 240, or may be attached to and controlled by a different lifting/lowering mechanism than clamping member 240. Where frame 254 is connected to clamping member 240, it may be desirable for the surfaces of contacts 252 and O-rings 46 to be substantially level with respect to each other in a direction parallel to the substrate surface so that the contacts 252 do not deform the substrate surface.

Contacts 252 may be made from any suitable material. Suitable materials include, but are not limited to, materials with poor thermal conductivity. This may help to reduce an amount of heat transferred from frame 254, which may be heated along with clamping member 240, to substrate 236. In some embodiments, the portion of contacts 252 that touch the substrate surface may be made of a different material than other portions of contacts 252. For example, the portions of contacts 252 that touch the substrate surface may be made from the same material or materials as O-rings 26 and 28. Suitable materials also include materials sufficiently strong and rigid to withstand the force exerted by the helium gas pressure. It will be appreciated that frame 254 may be heated along with clamping member 240 (as illustrated schematically at 260) to prevent the unwanted deposition of materials onto the frame. Likewise, in some embodiments, contacts 252 may also be heated where the amount of heat transferred to substrate 236 from contacts 252 is not detrimental to film growth.

The embodiments of FIGS. 2-10 disclose substrate clamping systems that utilize mechanical clamping force, or combinations of mechanical and electrostatic clamping forces, to clamp a substrate to temperature-controlled substrate holder 18. In alternative embodiments, a temperature-controlled substrate holder may utilize clamping forces other than, or in addition to, mechanical and electrostatic forces. For example, FIGS. 11-12 show a substrate clamping system that utilizes a magnetic clamping force to clamp a substrate into a substrate holder 318. Referring first to FIG. 11, substrate holder 318 includes a temperature-controlled chuck 330 and a clamping member 340. Chuck 330 includes a plurality of magnets 342 incorporated into and spaced around clamping base 338. Clamping member 340 includes a magnetic material, such as a ferromagnetic, ferrimagnetic, or paramagnetic material, that is attracted to magnets 342. In this manner, the magnetic attraction between chuck 330 and clamping member 340 helps to clamp a substrate with sufficient force to resist the pressure of helium on the substrate backside, even in a high vacuum environment. It will be appreciated that such a magnetic clamping mechanism may be used either alone or in combination with another suitable clamping mechanism. Furthermore, a movement system may be provided for moving clamping member 340 into and out of the magnetic fields produced by magnets 342 (where magnets 342 are permanent magnets), and/or for permitting a substrate to be inserted into and removed from the substrate holder. Examples of suitable movement systems include hydraulic and/or mechanical lifting systems.

Magnets 342 may be either permanent magnets or electromagnets. The use of electromagnets as magnets 342 may help in loading and unloading substrates from substrate holder 318, as turning off the flow of electrical current to the electromagnets may allow clamping member 340 to be removed more easily from clamping base 338. Furthermore, the use of electromagnets may allow variation of the clamping force exerted against the substrate by the adjustment of the electric current through the magnets. Clamping member 340 may include one or more reinforcement structures 341 to increase the rigidity of the structure to help prevent distortion.

FIG. 12 shows a sectional view of clamping member 340 and one of magnets 342. In FIG. 12, it can be seen that a small space 344 exists between clamping member 340 and magnet 342 when a substrate 336 is fully clamped into substrate holder. Configuring clamping member 340 and clamping base 338 such that space 344 exists when a substrate is clamped into substrate holder 218 helps to ensure that clamping member 340 does not contact clamping base 338 during clamping, which could reduce the clamping force against substrate 336. Space 344 further helps prevent the transfer of heat from clamping member 340 to chuck 330 via conductive modes. It can also be seen in this figure that clamping member 340 includes a recessed portion 346 configured to correctly position a substrate within the substrate holder 318. Furthermore, one or more seals or O-rings (not shown) may be positioned between clamping member 340 and substrate 336, and/or between chuck 330 and substrate 336, to help slow heat transfer between these parts.

While magnets 342 are shown in FIG. 12 as being disposed around a peripheral portion of chuck 330, it will be appreciated that the magnets may also be disposed around a clamping base such as that described earlier herein in the context of other embodiments, or in any other suitable location.

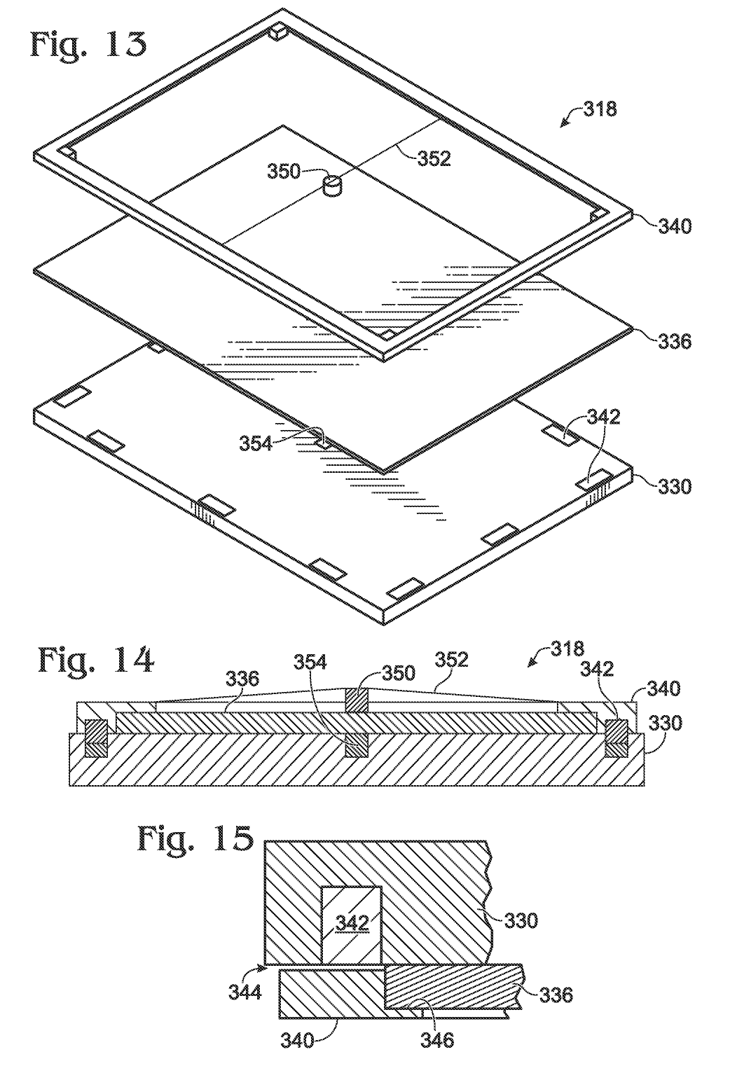

In some embodiments, additional clamping members may be provided that contact portions of the substrate intermediate the edges of clamping member 340. FIGS. 13-14 show an embodiment of a magnetic clamping member similar to that of FIGS. 11-12, but having an intermediate substrate contact 350 to provide resistance against the bowing of the substrate due to the pressure of helium against the substrate backside. Intermediate contact 350 is made at least partially of a ferromagnetic, ferromagnetic, or paramagnetic material, and is supported by a support structure 352. Likewise, temperature-controlled chuck 330 includes an intermediate magnet 354 that is located in a complimentary position to intermediate contact 350. The magnetic attraction of intermediate contact 350 by intermediate magnet 352 exerts a force on the substrate that opposes the force caused by the pressure of the heat exchange fluid against the backside of substrate 336, and thereby helps to resist bowing of the substrate caused by this force.

Intermediate contact 350 and intermediate contact support structure 352 may have any suitable configuration. For example, where substrate holder 318 is configured to be used to hold a substrate on which multiple devices are to be fabricated, intermediate contact may contact a region of substrate 336 between active device regions, as shown above for the embodiment of FIGS. 7-10. In this embodiment, intermediate contact 350 and support structure 352 may have any suitable size and shape that does not overlap with active device regions or otherwise interfere with the fabrication of the devices on substrate 336. Likewise, where intermediate contact 350 is configured to be used to hold a substrate on which a single device is to be fabricated, intermediate contact 350 and support structure 352 may be configured to have a minimal aspect ratio so as not to minimize any effect of the contact 350 and support structure 352 on the material deposition. For example, in these embodiments, support structure 352 may take the form of a thin wire member to which intermediate contact 350 is attached, and which suspends intermediate contact above chuck 330 when not in use, for example, when loading or unloading a substrate onto substrate holder 318.

A substrate may be clamped onto substrate holder 318 in any suitable manner. In one embodiment which utilizes electromagnets, a substrate is first moved into the deposition chamber, and then the substrate is lowered onto the chuck (for a face-up system) or onto the clamping member/substrate holder (for a face-down system, as depicted in FIG. 15). Next, the clamping member is moved into a clamping position such that the clamping member 318 contacts the front side of the substrate, and the chuck contacts the backside of the substrate. It will be appreciated that this contact may be achieved via seals, O-rings, or other like structure, as described above. Next, the electromagnets are activated, which causes the clamping member to clamp the substrate against the clamping base or chuck. Finally, helium or other suitable heat exchange gas is added to fill the space between the substrate backside and the chuck. Once the desired pressure of helium has been added, deposition may begin once the substrate reaches the desired deposition temperature.

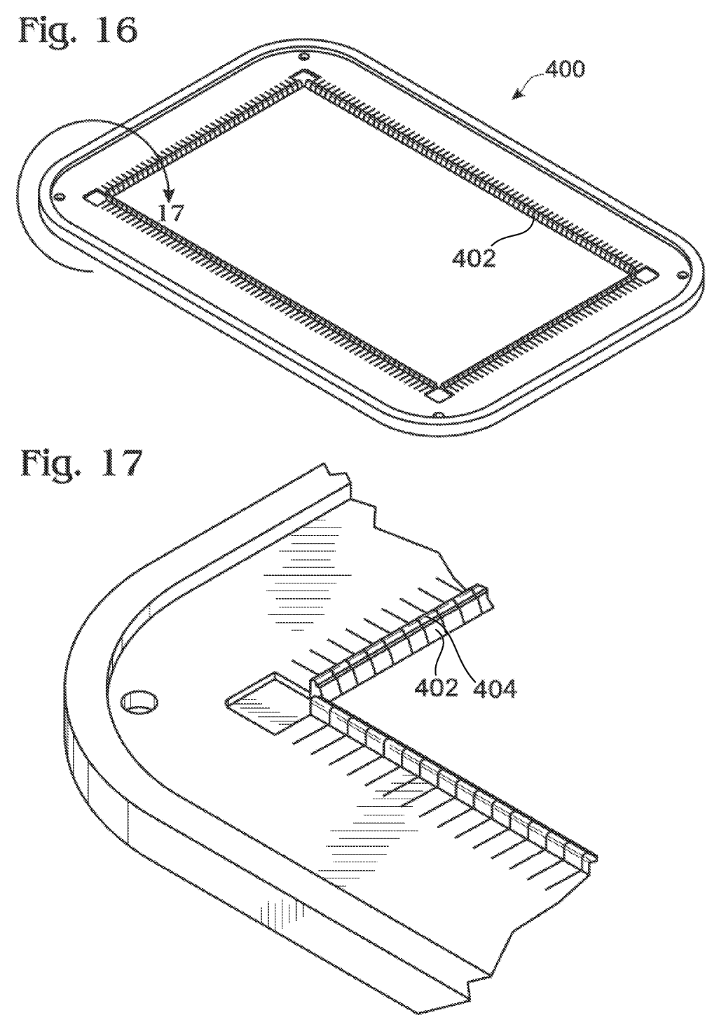

FIGS. 16 and 17 show an alternate embodiment of a clamping member 400 that may be used with the above-described embodiments, or with any other suitable substrate holding system. Instead of having a polymer seal for contacting a substrate, clamping member 400 includes a plurality of metal substrate contacts 402 that contact the perimeter region of a substrate to hold the substrate against a temperature-controlled chuck. Substrate contacts 402 may be configured to act as leaf springs, exerting a spring force against the substrate to hold a substrate tightly and uniformly against a cooled chuck. Such a design allows clamping member 400 to be formed entirely from metal, and therefore may simplify the fabrication of clamping member 400.

Substrate contacts 402 may have any suitable configuration, and may be separated by any suitable spacing or spacings. In some embodiments, the use of narrower, as opposed to wider, spacings between substrate contacts 402 may reduce an amount of material that is deposited on the perimeter region of a substrate, between the points of contact of substrate contacts 402 and the substrate edge. Examples of suitable spacings include, but are not limited to, spacings of 2 mm or less. In one specific example, spacings of 1.2 mm may separate the individual contacts 402. In other examples, spacings either smaller or larger than this may be used.

Substrate contacts 402 may be configured to have any suitable area of contact with a substrate. Where clamping member 400 is heated and is used with a cooled chuck, substrate contacts 402 may be configured to have a relatively small area of contact with a substrate. FIG. 17 shows one exemplary embodiment of this feature as a tapered end 404. This may help to slow heat transfer between the clamping member and the substrate.

Clamping member 400 and substrate contacts 402 may be made from any suitable material or materials. In one exemplary embodiment, both clamping member 400 and substrate contacts 402 are formed from aluminum. In other exemplary embodiments, other metals, such as a stainless steel, may be used. Furthermore, contacts 402 may include a thermally insulating material on those surfaces that contact the substrate to further help slow heat transfer to the substrate. It will be appreciated that where clamping member 400 is configured to be used in a magnetic clamping system, other materials (such as magnetic materials) may be used to form clamping member 400 or otherwise may be incorporated into clamping member 400.

It will be appreciated that the deposition system embodiments and substrate holder embodiments disclosed herein are exemplary in nature, and that these specific embodiments are not to be considered in a limiting sense, because numerous variations are possible. The subject matter of the present disclosure includes all novel and non-obvious combinations and subcombinations of the various deposition systems, substrate holders, and other features, functions and/or properties disclosed herein.

The following claims particularly point out certain combinations and subcombinations regarded as novel and nonobvious. These claims may refer to “an” element or “a first” element or the equivalent thereof. Such claims should be understood to include incorporation of one or more such elements, neither requiring nor excluding two or more such elements. Other combinations and subcombinations of the deposition systems, deposition chambers, deposition materials sources, substrate holders, substrate clamping mechanisms, and/or other features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

What is claimed is:

1. A system for depositing a vapor phase organic compound onto a substrate, comprising:
a vacuum chamber comprising a wall;
a wall heater in thermal communication with the wall of the vacuum chamber;
at least one of an evaporative source and a transport polymerization source configured to introduce the vapor phase organic compound into the chamber, and
a substrate holder disposed within the vacuum chamber, wherein the substrate holder comprises a cooled chuck, a heat transfer gas source for introducing a heat transfer gas to a space between the cooled chuck and the substrate, and a substrate clamping mechanism comprising at least one of an electrostatic, mechanical and magnetic clamping mechanism.

2. The system of claim 1, wherein the clamping mechanism comprising a clamping member configured to contact a portion of a device of the substrate.

3. The system of claim 2, wherein the clamping member includes a heater.

4. The system of claim 2, wherein the clamping mechanism further comprises a clamping base disposed at least partially around and spaced from the cooled chuck.

5. The system of claim 4, wherein the clamping member and clamping base are movable relative to one another.

6. The system of claim 4, further comprising a seal disposed between the clamping base and the cooled chuck.

7. The system of claim 4, further comprising a seal coupled to the cooled chuck, wherein the seal is configured to contact the substrate when the substrate is positioned on the substrate holder.

8. The system of claim 4, wherein the clamping member includes at least one magnetic portion, and wherein the clamping base includes an electromagnet.

9. The system of claim 2, further comprising a seal coupled to the clamping member, wherein the seal is configured to contact the substrate when the substrate is positioned on the substrate holder.

10. The system of claim 2, wherein the clamping member includes an outer contact structure having a closed perimeter defining an open central area, and an intermediate contact positioned within the open central area.

11. The system of claim 1, wherein the substrate holder is positioned in a face-up orientation in the vacuum chamber.

12. The system of claim 1, wherein the substrate holder is positioned in a face-down orientation in the vacuum chamber.

13. The system of claim 1, wherein the substrate holder is positioned in a generally side-facing orientation in the vacuum chamber.

14. A system for depositing a vapor phase organic compound onto a substrate, comprising:
a vacuum chamber comprising a wall;
a heater in thermal communication with the wall of the vacuum chamber; and
a substrate holding system disposed within the vacuum chamber, wherein the substrate holding system comprises a cooled chuck, a heat transfer gas source for introducing a heat transfer gas to a space between the cooled chuck and the substrate, and a substrate clamping device comprising a clamping member that operates via at least one of a mechanical and a magnetic clamping force, wherein the clamping member comprises a heating mechanism configured to heat the clamping member.

15. The system of claim 14, wherein the clamping device further comprises a clamping base disposed at least partially around and spaced from the cooled chuck.

16. The system of claim 15, wherein the clamping member and clamping base are movable relative to one another.

17. The system of claim 14, further comprising a seal disposed between the clamping base and the cooled chuck.

18. The system of claim 14, further comprising a seal coupled to the cooled chuck, wherein the seal is configured to contact the substrate when the substrate is positioned on the substrate holder.

19. The system of claim 14, wherein the clamping member comprises a magnetic portion, and wherein the clamping base includes an electromagnet.

20. The system of claim 1, further comprising a seal coupled to the clamping member, wherein the seal is configured to contact the substrate when the substrate is positioned on the substrate holder.

21. The system of claim 1, wherein the substrate holder is positioned in a face-down orientation in the vacuum chamber.

22. In an OLED manufacturing process, a method of depositing a vapor phase organic compound onto a substrate in a deposition chamber, the deposition chamber comprising a wall, the method comprising:
forming a vacuum in the chamber;
cooling the substrate to a temperature below a boiling point of the organic compound;
heating the wall of the deposition chamber to a temperature above the boiling point of the organic compound; and
introducing a vapor of the organic compound into the deposition chamber.

23. The method of claim 22, wherein cooling the substrate includes cooling the substrate to a temperature of approximately 20 degrees Celsius to −40 degrees Celsius.

24. The method of claim 22, wherein heating the wall of the deposition chamber includes heating the wall of the deposition chamber to a temperature of approximately 20-65 degrees Celsius.

25. The method of claim 22, wherein the organic compound comprises a parylene-based reactive intermediate compound.

26. The method of claim 25, wherein the parylene-based reactive intermediate compound comprises *CF₂C₆H₄CF₂*, wherein * denotes a free radical.

27. The method of claim 22, further comprising clamping the substrate to a cooled substrate holder via a mechanical clamp.

28. The method of claim 27, further comprising heating the mechanical clamp while cooling the substrate.

29. The method of claim 28, wherein heating the mechanical clamp includes heating the mechanical clamp to a temperature of approximately 20-65 degrees Celsius.

30. The method of claim 27, wherein the cooled substrate holder includes a cooled chuck, further comprising adding a heat exchange fluid to a space between the substrate and a cooled chuck of the substrate holder.

31. The method of claim 30, wherein the heat exchange fluid is helium gas, and wherein the helium gas is added to the space between the substrate and the cooled chuck at a pressure of approximately 3 Torr or greater.

32. The method of claim 22, further comprising clamping the substrate to a cooled substrate holder via a magnetic clamp.

33. The method of claim 22, further comprising clamping the substrate to a cooled holder via an electrostatic mechanism.
